(19) United States
(12) Patent Application Publication
(10) Pub. No.: US 2024/0312761 A1
(43) Pub. Date: Sep. 19, 2024

(54) DRAWING DEVICE AND DRAWING METHOD

(71) Applicant: Kioxia Corporation, Tokyo (JP)

(72) Inventor: Yoshinori KAGAWA, Shinagawa Tokyo (JP)

(21) Appl. No.: 18/593,629

(22) Filed: Mar. 1, 2024

(30) Foreign Application Priority Data
Mar. 17, 2023 (JP) 2023-043239

(51) Int. Cl. H01J 37/302; G03F 1/78; H01J 37/20; H01J 37/317

(52) U.S. Cl. CPC H01J 37/3026; G03F 1/78; H01J 37/20; H01J 37/3174; H01J 2237/202

(57) ABSTRACT

A drawing device includes a device configured to generate a beam of charged particles, a group of optical elements disposed in a path of the beam, the group of optical elements being controlled so that the beam irradiates each of a plurality of divided regions of a target drawing region on which a pattern is to be drawn with the beam, and a control computer configured to divide the target drawing region into the divided regions based on a density of the pattern, and to execute first to n-th irradiations (n is an integer of 2 or more) selectively on the divided regions so that a total irradiation amount of the beam on each of the divided regions reaches a required irradiation amount therefor.

### CROSS-REFERENCE TO RELATED APPLICATION(S)

This application is based upon and claims the benefit of priority from Japanese Patent Application No. 2023-043239, filed Mar. 17, 2023, the entire contents of which are incorporated herein by reference.

### FIELD

Embodiments described herein relate generally to a drawing device and a drawing method.

### BACKGROUND

Templates for lithography masks and nanoimprint lithography used in semiconductor manufacturing processes are formed by performing processes by using a resist or the like drawn by an electron beam drawing device, as a mask. The drawing device calculates the irradiation amount for each pattern from drawing pattern data and drawing conditions, and draws the pattern on a mask blank by using the irradiation amount for each pattern. At this time, a stage speed is set to a speed that matches the pattern with a large irradiation amount. For this reason, even for the pattern with a small irradiation amount, the stage speed may become slower than necessary. In this case, in the pattern with the small irradiation amount, although the stage is operating, the stage may not be irradiated with the electron beam, resulting in wasteful operations. Such wasteful operations prolong the overall drawing time.

### DESCRIPTION OF THE DRAWINGS

FIG. 1 is a schematic configuration diagram of a drawing device according to a first embodiment.

FIG. 2 is a conceptual diagram illustrating a configuration of a shaping aperture member.

FIG. 3 is a conceptual diagram illustrating a drawing operation in the first embodiment.

FIG. 4 is a diagram illustrating an example of an irradiation region and drawing pixels of one shot of a multi-beam.

FIGS. 5-8 are conceptual diagrams illustrating the drawing operation on a substrate by the drawing device according to the first embodiment.

FIG. 9 is a graph illustrating a relationship between a pattern density and an irradiation amount.

FIG. 10 is a table illustrating a relationship between a maximum irradiation amount of each of first to fourth irradiations and a divided region of an irradiation target according to a second embodiment.

FIGS. 11-14 are conceptual diagrams illustrating a drawing operation on a substrate by a drawing device according to the second embodiment.

FIG. 15 is a graph illustrating a relationship between a pattern density and an irradiation amount.

FIG. 16 is a conceptual diagram illustrating a drawing operation on a substrate by a drawing device according to a third embodiment.

FIG. 17 is a graph illustrating a relationship between a pattern density and an irradiation amount according to the third embodiment.

FIGS. 18-20 are conceptual plan views of a substrate for illustrating an irradiation position correction process according to a fourth embodiment.

FIGS. 21-22 are conceptual cross-sectional views of a substrate for illustrating an irradiation position correction process according to a fifth embodiment.

FIG. 23 is a graph illustrating a relationship between a correction amount of a beam irradiation position and a beam irradiation time.

### DETAILED DESCRIPTION

Embodiments provide a drawing device and a drawing method capable of shortening a drawing time for a substrate.

In general, according to one embodiment, a drawing device includes a device configured to generate a beam of charged particles, a group of optical elements disposed in a path of the beam, the group of optical elements being controlled so that the beam irradiates each of a plurality of divided regions of a target drawing region on which a pattern is to be drawn with the beam, and a control computer configured to divide the target drawing region into the divided regions based on a density of the pattern, and to execute first to n-th irradiations (n is an integer of 2 or more) selectively on the divided regions so that a total irradiation amount of the beam on each of the divided regions reaches a required irradiation amount therefor.

Embodiments of the present disclosure will be described below with reference to the drawings. This embodiment does not limit the scope of the present disclosure. The drawings may be schematic or conceptual. In the specification and drawings, the same elements are denoted by the same reference numerals.

### First Embodiment

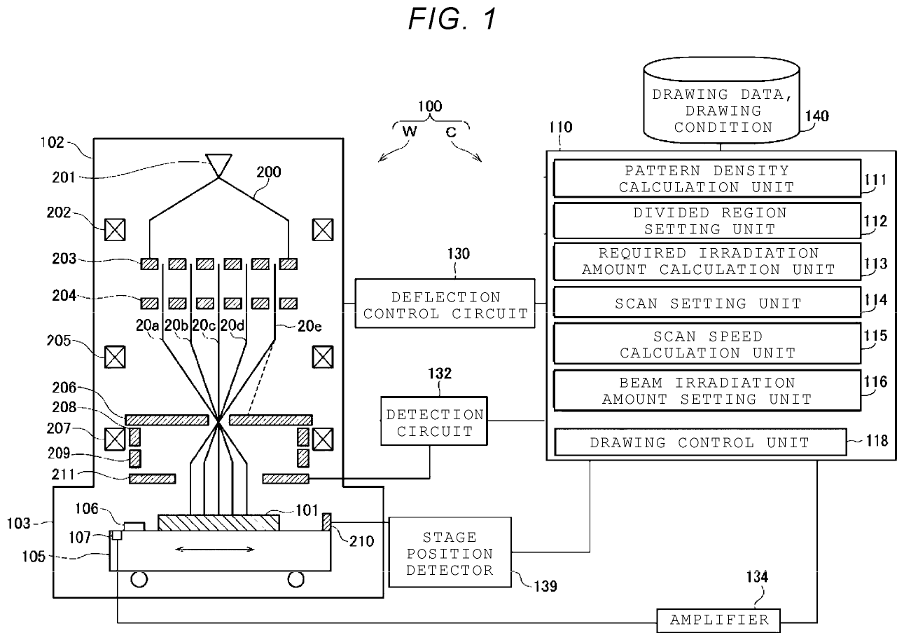

FIG. 1 is a schematic configuration diagram of a drawing device according to a first embodiment. A drawing device 100 includes a drawing unit W and a control unit C. The drawing device 100 may be, for example, a multi-charged particle beam drawing device. The drawing unit W includes an electronic lens barrel 102 and a drawing chamber 103. The electron lens barrel 102 includes an electron gun 201, an illumination lens 202, a shaping aperture member 203, a blanking plate 204, a reduction lens 205, a limiting aperture member 206, an objective lens 207, deflectors 208 and 209, and a detector 211. The electron lens barrel 102 generates a multi-beam of charged particles that draws on a drawing region on a substrate 101. Any of the lens (such as the illumination lens 202, the reduction lens 205, and the objective lens 207), apertures (such as the shaping aperture member 203 and the limiting aperture member 206), the blanking plate 204, and the deflectors 208 is referred to herein as an optical element, which is defined generally as a component that alters a path or a shape of a beam.

An XY stage 105 is located in the drawing chamber 103. The substrate 101 to be imaged is located on the XY stage 105. The substrate 101 is, for example, a mask blank, a template blank, or a semiconductor substrate (e.g., silicon wafer).

A mark 106, a Faraday cup 107, and a mirror 210 for position measurement are located on the XY stage 105. An output of the Faraday cup 107 is output to a control computer 110 via an amplifier 134.

The control unit C includes the control computer 110, a deflection control circuit 130, a detection circuit 132, the amplifier 134, a stage position detector 139, and a storage unit 140. In the storage unit 140, drawing data and drawing conditions are input from the outside and stored. The drawing data usually includes information about the plurality of figure patterns for drawing. For example, the figure code, coordinates, size, and the like are defined for each figure pattern in the information. Further, the drawing data includes data indicating a portion on which the drawing device performs the drawing operation, that is, a portion on which the beam irradiation is performed. The drawing conditions include information such as a minimum multiplicity, a maximum multiplicity, and a required irradiation amount to be applied to a resist material. As used herein, “multiplicity” is defined as the number of times that the drawing region of the substrate 101 is repeatedly irradiated with the beam. The required irradiation amount to be applied to the resist material is based on a property of the resist material such as its sensitivity to having a pattern formed thereon.

The control computer 110 includes a pattern density calculation unit 111, a divided region setting unit 112, a required irradiation amount calculation unit 113, a scan setting unit 114, a scan speed calculation unit 115, a beam irradiation amount setting unit 116, and a drawing control unit 118. These units are functional units of the control computer 110 that are implemented in software running on a central processing unit (CPU) of the control computer 110. Alternatively, these units may be implemented in hardware such as an electric circuit, e.g., programmable logic controller (PLC), or may be implemented in a combination of hardware and software.

The pattern density calculation unit 111 calculates the density of the pattern to be drawn in the drawing region based on the drawing data stored in the storage unit 140. As described above, the drawing data indicates a drawing region on the surface of the substrate 101 where the beam irradiation is performed to form the pattern on the resist on the semiconductor wafer. Therefore, the pattern density calculation unit 111 can calculate the density of the pattern of each drawing region based on the drawing data. The drawing data with a small figure area per unit area has low pattern density, and the drawing data with a large figure area per unit area has high pattern density. As described above, since the drawing data specifies a region where the beam irradiation is performed, if the resist material is a positive resist and is removed by the beam irradiation, the drawing data would specify a shape inversed from the pattern to be transferred to the semiconductor wafer. On the other hand, if the resist material is a negative resist and the pattern is formed by the beam irradiation, the drawing data would specify a shape matching the pattern to be transferred to the semiconductor wafer. Hereinafter, the resist material will be explained as a positive resist.

The divided region setting unit 112 virtually divides the drawing region into a plurality of divided regions DR1 to DR3, as illustrated in FIG. 5, based on the pattern density in the drawing region calculated by the pattern density calculating unit 111. For example, first and second threshold values (first threshold value <second threshold value) are set for the pattern density, and the first and second threshold values are stored in the storage unit 140. For example, the divided region setting unit 112 virtually divides the drawing region into the region DR1 with the pattern density lower than the first and second threshold values, the region DR2 with the pattern density higher than the first threshold value and lower than the second threshold value, and the region DR3 with the pattern density higher than the first and second threshold values. It is noted that the number of threshold values and the number of divided regions are not limited to these examples.

The required irradiation amount calculation unit 113 calculates the required beam irradiation amount for each of the plurality of divided regions DR1 to DR3. The required irradiation amount is the irradiation amount (dose amount, exposure amount) of the charged particle beam required to expose the resist material with a predetermined pattern according to the drawing data and changes according to the pattern density. For example, among the divided regions DR1 to DR3, the divided region DR1 with the low pattern density is required to be exposed with the beam than the divided regions DR2 and DR3. Therefore, the required irradiation amount calculation unit 113 sets the required irradiation amount for the divided region DR1 to be larger than that for the other divided regions DR2 and DR3. Among the divided regions DR1 to DR3, for the divided region DR3 with the high pattern density, the required radiation amount is less than that for the divided regions DR1 and DR2. Therefore, the required irradiation amount calculation unit 113 sets the required irradiation amount for the divided region DR3 to be smaller than that of the other divided regions DR1 and DR2.

The scan setting unit 114 determines the number of irradiations of the beam for each of the divided regions DR1 to DR3 based on the required irradiation amount for the divided regions DR1 to DR3. For example, when performing the first to n-th irradiations of the beam (n is an integer of 2 or more), the scan setting unit 114 determines whether to perform the first to n-th irradiations for each of the divided regions DR1 to DR3 so that the total irradiation amount in the first to n-th irradiations of the beam becomes equal to the required irradiation amount or more for the divided regions DR1 to DR3, respectively.

The scan speed calculation unit 115 determines the beam scan speed, that is, the stage speed, for each of the divided regions DR1 to DR3. Since the region to be irradiated with the beam is fixed, scanning the beam is actually determined by the stage speed as the beam passes through an exposure region by changing the stage speed. For example, when the beam irradiation is performed on the divided regions DR1 to DR3, the scan speed calculation unit 115 determines the beam scan speed (which is equal to the stage speed) for each of the divided regions DR1 to DR3. It is noted that, in the first embodiment, the scan speed is constant.

The beam irradiation amount setting unit 116 determines the beam irradiation amount for each of the divided regions DR1 to DR3. Hereinafter, the irradiation amount of beam will be referred to as a “beam irradiation amount.” It is noted that the irradiation amount per unit area of the drawing region is simply referred to as an “irradiation amount.” Further, when the drawing region is irradiated with the beam multiple times, the total irradiation amount per unit area of the drawing region is referred to as a “total irradiation amount.” The required irradiation amount is the irradiation amount required to expose the resist material in the predetermined pattern.

The drawing control unit 118 moves the XY stage 105 according to the scan speed determined by the scan speed calculation unit 115, that is, the stage speed.

The stage position detector 139 emits the laser, receives reflected light from the mirror 210, and detects the position of the XY stage 105 by laser interferometry.

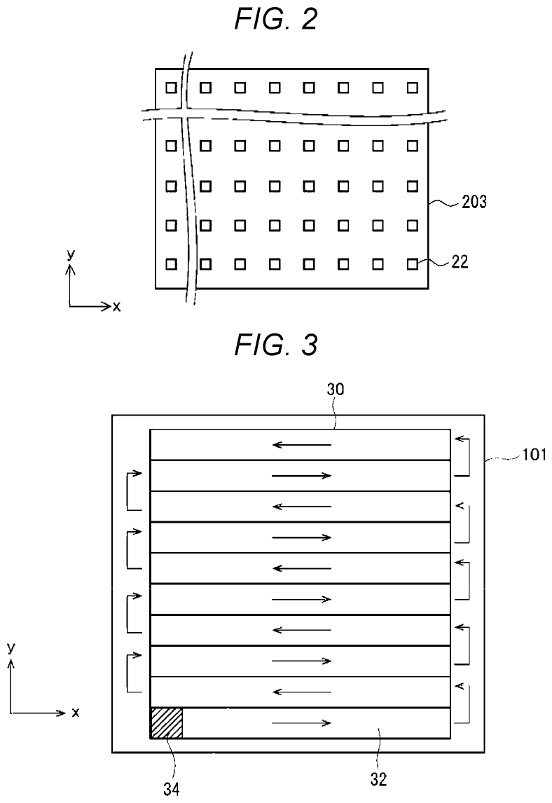

FIG. 2 is a conceptual diagram illustrating a configuration of the shaping aperture member 203. In the shaping aperture member 203, apertures 22 are formed in m rows vertically (in the y direction) and n columns horizontally (in the x direction) (m, n≥2) at a predetermined arrangement pitch. Each aperture 22 is formed in a rectangular shape with the same size and shape. Alternatively, each aperture 22 may be circular with the same outer diameter. A portion of an electron beam 200 passes through each of the plurality of apertures 22, so that multi-beams 20a to 20c are formed.

The blanking plate 204 of FIG. 1 has passage holes formed in accordance with the arrangement positions of the apertures 22 of the shaping aperture member 203. Multiple pairs of electrodes (referred to herein as blankers) are located in each passage hole. The electron beams passing through each passage hole are independently controlled to be in a beam-on or beam-off state by a voltage applied to the blanker. When the beam is on, opposing electrodes of the blanker are controlled to be at the same potential, and the blanker does not deflect the beam. When the beam is off, opposing electrodes of the blanker are controlled to be at different potentials, and the blanker deflects the beam. In this manner, the plurality of blankers perform blanking deflection of the corresponding beams among the multi-beams passing through the plurality of apertures 22 of the shaping aperture member 203.

The electron beam 200 emitted from the electron gun 201 illuminates the entire shaping aperture member 203 almost vertically by the illumination lens 202. The electron beam 200 illuminates the region including all the apertures 22. When the electron beam 200 passes through the plurality of apertures 22 of the shaping aperture member 203, for example, a plurality of rectangular electron beams (referred to herein as multi-beams) 20a to 20e are formed.

The multi-beams 20a to 20e pass through the corresponding blankers of the blanking plate 204. Each blanker individually deflects the passing electron beam. The multi-beams 20a to 20e passing through the blanking plate 204 are demagnified by the reduction lens 205 and ideally will pass through the same point on the limiting aperture member 206 with all the beams on. A trajectory of the beam is adjusted by using an alignment coil (not illustrated) so that this point is located in the central aperture of the limiting aperture member 206.

Herein, the beam controlled to the beam-off state is deflected by the blanker of the blanking plate 204 and passes through the trajectory passing outside the aperture of the limiting aperture member 206, so that the beam is blocked by the limiting aperture member 206. On the other hand, since the beam controlled to be in the beam-on state is not deflected by the blanker, the beam passes through the aperture of the limiting aperture member 206. In this manner, the on/off of the beam is controlled by the blanking control of the blanking plate 204.

The limiting aperture member 206 blocks each beam deflected by the plurality of blankers in the beam-off state. Then, the multi-beam for one shot is formed by the beam passing through the limiting aperture member 206 from the time it is turned on until the time it is turned off.

The multi-beams passing through the limiting aperture member 206 are focused by the objective lens 207 and projected onto the substrate 101 at a desired reduction ratio. Each of the deflectors 208 and 209 deflects the entire multi-beam by the same direction and distance. Deflection amounts of the deflectors 208 and 209 are independently controlled. An irradiation position of the multi-beam on the substrate 101 is controlled by the deflectors 208 and 209.

During the drawing, the XY stage 105 is controlled to move continuously. Although the moving speed of the XY stage 105 is constant in the first embodiment, the moving speed of the XY stage 105 may be variable as described in other embodiments. The beam irradiation position is controlled by the deflector 208 so as to follow the movement of the XY stage 105. The multi-beams irradiated simultaneously are ideally located at a pitch obtained by multiplying the arrangement pitch of the plurality of apertures of the shaping aperture member 203 by the above-described desired reduction ratio. During the drawing, the multi-beam performs a raster scan type drawing operation in which all pixels defined on the substrate 101 are exposed by the position control using the deflection. When the beam is on a pixel that does not include the pattern, the beam is controlled to be turned off by blanking control.

FIG. 3 is a conceptual diagram illustrating the drawing operation in this embodiment. As illustrated in FIG. 3, for example, a drawing region 30 on the substrate 101 is virtually divided into a plurality of stripe regions 32 having a stripe shape and a predetermined width in the y direction. When drawing these stripe regions 32, the XY stage 105 is first moved so that an irradiation region 34 that can be irradiated with one multi-beam irradiation is adjusted so as to be located at the left end of the first stripe region 32 and the drawing starts.

When drawing the first stripe region 32, the XY stage 105 is moved continuously in a-x direction to perform drawing in a +x direction. After drawing the first stripe region 32, the XY stage 105 stops. Next, the stage position is moved in the −y direction in an amount equal to the stripe width or smaller so that the beam array 34 is located at the right end of the second stripe region 32. Subsequently, by continuously moving the XY stage 105 in the +x direction, the drawing is performed on the substrate 101 in the −x direction.

In the third stripe region 32, drawing is performed in the +x direction, and in the fourth stripe region 32, drawing is performed in the −x direction. Although each stripe region 32 may be drawn in the same direction, in this case, the operation of returning the stage position is added after the drawing, so that the drawing time becomes longer.

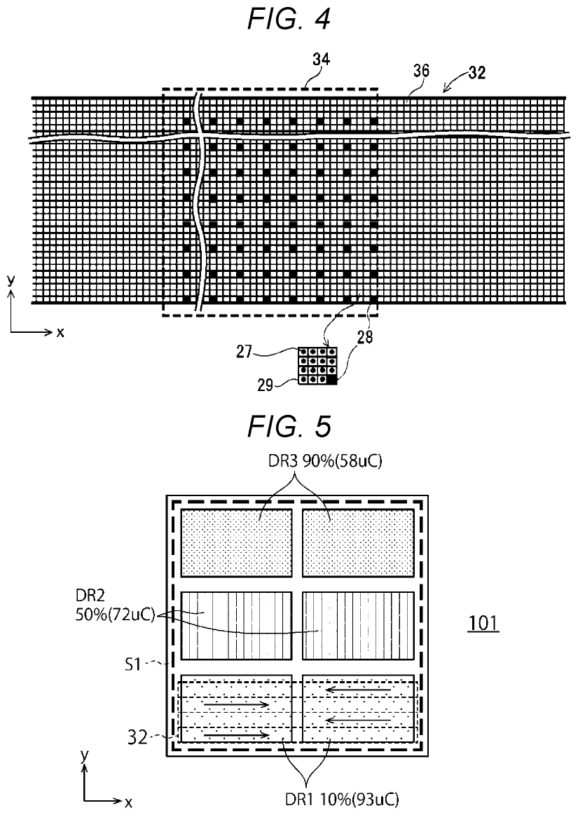

FIG. 4 is a diagram illustrating an example of an irradiation region and drawing pixels of one multi-beam shot. In the stripe region 32, for example, a plurality of control grids 27 are set, which are located in a grid pattern at the pitch of the beam size of the multi-beam on the surface of the substrate 101. For example, it is preferable to set the arrangement pitch to about 10 nm.

The plurality of control grids 27 become ideal irradiation positions where there is no deviation of the multi-beams. The arrangement pitch of the control grids 27 is not limited to the same size as the beam size, and may be any size that can be controlled as the deflection position of the deflector 209. Then, the plurality of pixels 36 are set, which are virtually divided in a mesh shape with each control grid 27 at the center, and have the same size as the arrangement pitch of the control grids 27.

Each pixel 36 becomes a unit area irradiated per one beam of the multi-beam. The example of FIG. 4 illustrates the case where the drawing region of the substrate 101 is divided into the plurality of stripe regions 32 with the same width as the size of the beam array 34 that can be irradiated with one multi-beam 20 in the y direction. The size of the beam array 34 in the x direction is a value obtained by multiplying an inter-beam pitch in the x direction of the multi-beam by the number of beams in the x direction. The size of the beam array 34 in the y direction is the value obtained by multiplying the inter-beam pitch in the y direction of the multi-beam by the number of beams in the y direction.

FIG. 4 illustrates an example of the multi-beams of 8×8 columns. It is noted that the multi-beam is not limited to 8×8 columns, and 512×512 columns or the like may be used as appropriate. Therefore, in the beam array 34, the plurality of pixels 28 that are irradiated with one multi-beam shot are illustrated as black pixels. In other words, the pitch between adjacent pixels 28 is the pitch between each beam of the designed multi-beam. Herein, the region having the size of the beam pitch is defined as the sub-irradiation region 29. In the example of FIG. 4, each sub-irradiation region 29 is configured with 4×4 pixels.

When drawing each stripe region 32, the drawing is performed by using a raster scan method in which, while the XY stage 105 is moved in the x direction, the beam array is deflected by the deflector 209 so that the pixels exposed by each shot is moved in the y direction, and the shot beam irradiation is performed continuously in sequence.

When drawing each stripe region 32, the beam position is controlled by the deflector 208 in parallel with the continuous movement of the XY stage 105 in the x direction to expose pixels on the substrate 101. At this time, the deflector 208 controls switching of the exposure pixels and deflection of the beam position so that the beam being exposed follows the continuous movement of the substrate 101. The deflector 208 deflects the beam array in the sub-irradiation region 29 when switching exposure pixels.

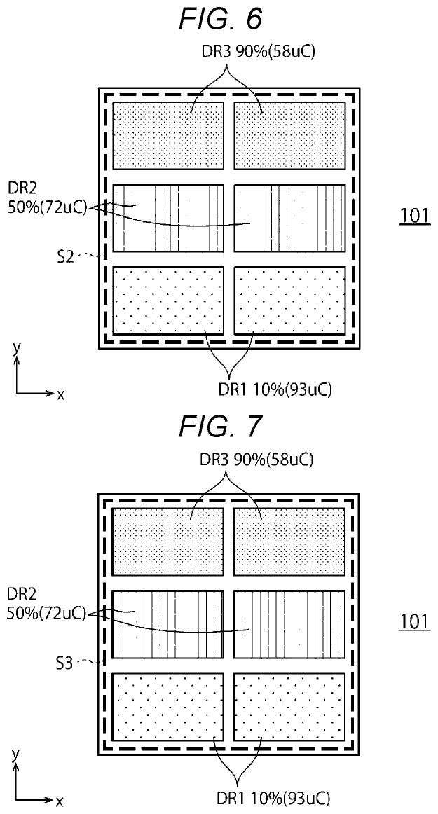

FIGS. 5 to 8 are conceptual diagrams illustrating the drawing operation on the substrate by the drawing device according to the first embodiment. The divided region setting unit 112 virtually divides the entire drawing region of the substrate 101 into the plurality of divided regions DR1 to DR3 based on the density of the drawn pattern. For example, the first threshold value is assumed to be 30% and the second threshold value is assumed to be 60%. Further, as illustrated in FIG. 5, the pattern density of the divided region DR1 is assumed to be, for example, 10%, the pattern density of the divided region DR2 is assumed to be, for example, 50%, and the pattern density of the divided region DR3 is assumed to be, for example, 90%. In this case, the drawing region is virtually divided into the divided region DR1 with the pattern density lower than 30%, the divided region DR2 with the pattern density higher than 30% and lower than 60%, and the divided region DR3 with the pattern density higher than 60%. In this manner, the divided region setting unit 112 divides the drawing region into the plurality of divided regions DR1 to DR3 based on the pattern density of the drawing region. In FIG. 5, the divided regions DR1 to DR3 are located in the same shape sequentially from the bottom of the figure for convenience. However, in reality, the divided regions may exist in various regions and in various shapes in the drawing region.

The required beam irradiation amount is set for each of the plurality of divided regions DR1 to DR3. For example, the relational expression of the required irradiation amount to the pattern density is stored in the storage unit 140 in advance. The required irradiation amount calculation unit 113 calculates the required irradiation amount for each of the divided regions DR1 to DR3 by using the relational expression of the required irradiation amount to the pattern density. The required irradiation amount calculation unit 113 may change the required irradiation amount by using proximity effect correction in order to reduce variations in dimensions due to the pattern density of the divided regions DR1 to DR3. For example, the required irradiation amount calculation unit 113 sets the required irradiation amount for the divided region DR1 with the low pattern density of 10% to 93 microcoulombs (μC), sets the required irradiation amount for the divided region DR2 with the medium pattern density of 50% to 72 μC, and sets the required irradiation amount for the divided region DR3 with the high pattern density of 90% to 58 μC. It is noted that the relational expression of the required irradiation amount to the pattern density varies according to the sensitivity of the resist material.

The scan setting unit 114 determines the number of irradiations of the beam for each of the divided regions DR1 to DR3 based on the required irradiation amount for each of the divided regions DR1 to DR3. In the first embodiment, it is assumed that the beam irradiation amount is approximately constant, and the beam scanning speed with respect to the substrate 101, that is, the stage speed is also approximately constant. In this case, the irradiation amount from one beam irradiation is also approximately constant. For example, when performing the first to n-th irradiations (n is the integer of 2 or more), the scan setting unit 114 determines whether to perform the first to n-th irradiations for each of the divided regions DR1 to DR3 based on the required irradiation amount for each of the divided regions DR1 to DR3. That is, the scan setting unit 114 determines the number of irradiations of the beam for each of the divided regions DR1 to DR3 so that the total irradiation amount for each of the divided regions DR1 to DR3 becomes the required irradiation amount or more. The total irradiation amount of the beam for each of the divided regions DR1 to DR3 is determined by the number of irradiations of the beam.

For example, as illustrated in FIGS. 5 to 8, the drawing device 100 executes the first to fourth irradiations S1 to S4. As illustrated in FIGS. 5 to 7, in the first to third irradiations S1 to S3, all of the divided regions DR1 to DR3 (the entire drawing region) are irradiated with the beam. In each of the first to third irradiations S1 to S3, the drawing device 100 draws on the drawing region by using the raster scan method. For example, when the irradiation amount in one irradiation is 25 μC, by the first to third irradiations S1 to S3, the irradiation can be performed with the beam up to the total irradiation amount of 75 μC. In this case, the total irradiation amount (75 μC) reaches the required irradiation amount (72 μC) for the divided region DR2 and the required irradiation amount (58 μC) for the divided region DR3. Therefore, no more beam irradiation is required for the divided regions DR2 and DR3.

On the other hand, the total irradiation amount (75 μC) does not reach the required irradiation amount (93 μC) for the divided region DR1. Therefore, additional irradiation is required for the divided region DR1. Herein, as illustrated in FIG. 8, in the fourth irradiation S4, only the divided region DR1 (a portion of the drawing region) is irradiated with the beam. Also, in the fourth irradiation S4, the drawing device 100 draws on the drawing region by using the raster scan method. The fourth irradiation S4 is not performed on the divided regions DR2 and DR3. In the fourth irradiation S4, only the divided region DR1 is irradiated with the beam having the irradiation amount of up to 25 μC. That is, the total irradiation amount in the first to fourth irradiations S1 to S4 for the divided region DR1 is 100 μC. The total irradiation amount (100 μC) reaches the required irradiation amount (93 μC) for the divided region DR1. Therefore, by the first to fourth irradiations S1 to S4, the total irradiation amount becomes the required irradiation amount or more in the entire drawing region.

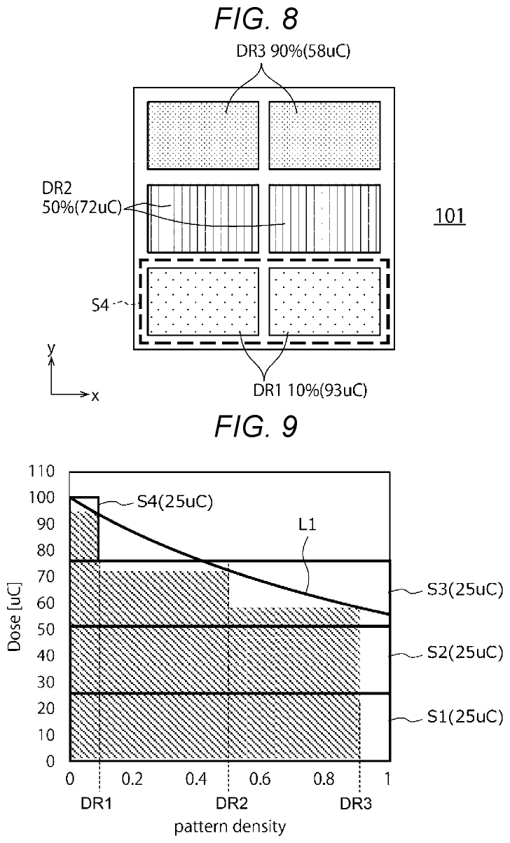

FIG. 9 is a graph illustrating a relationship between the pattern density and the irradiation amount. The vertical axis indicates the total irradiation amount (dose amount) (μC). The horizontal axis indicates the pattern density. A line L1 indicates the required irradiation amount for the pattern density. The relational expression for line L1 is stored in the storage unit 140 in advance. The pattern density of the divided region DR1 is 0.1 (10%), and the required irradiation amount for the divided region is 93 μC. The pattern density of the divided region DR2 is 0.5 (50%), and the required irradiation amount for the divided region is 72 μC. The pattern density of the divided region DR3 is 0.9 (90%), and the required irradiation amount for the divided region is 58 μC.

Furthermore, each of the first to fourth irradiations S1 to S4 has the irradiation amount of 25 μC. The first to third irradiations S1 to S3 are applied for the divided regions DR1 to DR3 (the entire drawing region). Accordingly, the total irradiation amount for the divided regions DR2 and DR3 becomes 75 μC, which becomes the respective required irradiation amount (72 μC, 58 μC) or more. The fourth irradiation S4 is applied only for the divided region DR1. Accordingly, the total irradiation amount for the divided region DR1 becomes 100 μC, which becomes the required irradiation amount (93 μC) or more for the divided region DR1.

It is noted that the order of execution of the first to fourth irradiations S1 to S4 does not matter. S4, S3, S2, and S1 may be executed in this order. Furthermore, the process may start from any of the first to fourth irradiations S1 to S4 and may end at any of the irradiations. Further, in this embodiment, the first to fourth irradiations S1 to S4 are described, but the number of irradiations is not limited to four, and may be n times. Furthermore, the drawing region is virtually divided into the three divided regions DR1 to DR3. However, the number of divisions of the drawing region is not particularly limited.

In this manner, the drawing device 100 according to the present embodiment irradiates the divided regions DR1 to DR3 (the entire drawing region) with the beam in the first to third irradiations. In the fourth irradiation, the drawing device 100 irradiates only the divided region DR1 with the beam where the total irradiation amount does not reach the required irradiation amount. Accordingly, in the fourth irradiation, the divided region DR1 can be partially irradiated with the beam while omitting the beam irradiation for the divided regions DR2 and DR3.

According to this embodiment, the beam irradiation amounts in the first to fourth irradiations are equal, and the beam scanning speeds, that is, the stage speeds in the first to fourth irradiations are also equal. Therefore, the control computer 110 can virtually divide the drawing region into the divided regions DR1 to DR3 according to the pattern density of the drawing region and can determine the required beam irradiation amount based on the pattern density for each of these divided regions DR1 to DR3. Further, the control computer 110 determines whether to perform the first to fourth irradiations according to the required irradiation amounts for each of the divided regions DR1 to DR3. Accordingly, without performing the beam irradiation, the wasteful scanning operation in which only the stage operation is performed and the wasteful operation of the XY stage 105 can be omitted, and the drawing time for the substrate 101 can be shortened.

In the first to fourth irradiations, the total irradiation amount in each divided region DR1 to DR3 is determined depending on the region to which the beam is irradiated. The total beam irradiation amount for each of the divided regions DR1 to DR3 can be up to the sum of the beam irradiation amounts from the first to fourth irradiations. The drawing device 100 executes the first to fourth irradiations for the divided regions DR1 to DR3 based on the determination by the control computer 110. Accordingly, the control computer 110 can control the electron lens barrel 102 and the drawing chamber 103 so that the total irradiation amount of the beam in the first to fourth irradiations becomes the required irradiation amount or more of the beam in the drawing region. Accordingly, while the wasteful operation in which the beam irradiation is not performed and the wasteful operation of the XY stage 105 are omitted, the respective required irradiation amount or more for the divided regions DR1 to DR3 can be obtained.

### Second Embodiment

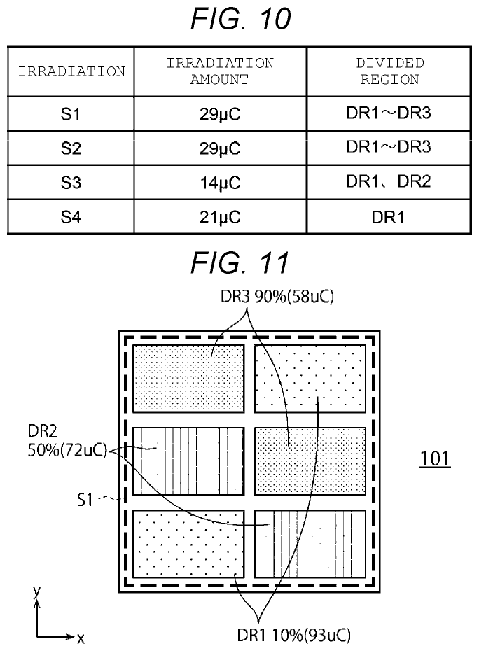

FIG. 10 is a table illustrating a relationship between the maximum irradiation amount of each of the first to fourth irradiations and the divided regions of the irradiation target according to the second embodiment. In the second embodiment, the control computer 110 can vary the beam irradiation amount in the first to fourth irradiations based on the pattern density of the drawing region and the drawing conditions. When the beam irradiation amount differs, the irradiation amount in one beam irradiation (that is, the irradiation amount of the first to fourth irradiations S1 to S4) also differs. The beam irradiation amount may be changed by adjusting the output of the electron gun 201 while using the beam irradiation time constant or may be changed by adjusting the beam irradiation time while using the output of the electron gun 201 constant. Further, the beam irradiation amount may be changed by adjusting both the beam irradiation time and the output of the electron gun 201.

This is the same as in the first embodiment in that the control computer 110 determines the required beam irradiation amount for the divided regions DR1 to DR3 based on the pattern density of the divided regions DR1 to DR3.

The drawing conditions include information such as the minimum multiplicity, maximum multiplicity, and resist material. The minimum multiplicity is a minimum number of times that the same drawing region is repeatedly irradiated with the beam. The minimum multiplicity can be said to be the number of times that the drawing region is irradiated with the beam of the same irradiation amount. The drawing device 100 irradiates the drawing region with the beam of at least the minimum multiplicity. The maximum multiplicity is a maximum number of times that the same drawing region is repeatedly irradiated with the beam. The drawing device 100 cannot irradiate the drawing region with the beam exceeding the maximum multiplicity. The information on the resist material includes the sensitivity of the resist material to the beam. The information on the resist material is one of elements for setting the required beam irradiation amount for the divided regions DR1 to DR3. Therefore, the control computer 110 determines the required beam irradiation amount for the divided regions DR1 to DR3 based on the sensitivity of the resist material formed on the substrate 101. For example, if the resist material is highly sensitive, the control computer 110 decreases the required beam irradiation amount. If the resist material is less sensitive, the control computer 110 increases the required beam irradiation amount. It is noted that the drawing conditions may be input into the drawing device 100 by the operator.

The beam irradiation amount setting unit 116 determines the beam irradiation amount in the first to fourth irradiations S1 to S4 based on drawing conditions such as the minimum multiplicity, the maximum multiplicity, and the resist material information and the required irradiation amount for the divided regions DR1 to DR3.

The scan setting unit 114 determines whether to irradiate each of the divided regions DR1 to DR3 based on the required beam irradiation amount for the divided regions DR1 to DR3 and the beam irradiation amount in the first to fourth irradiations S1 to S4.

For example, it is assumed that the minimum multiplicity is 2 and the maximum multiplicity is 4. In this case, the control computer 110 sets the entire drawing region so as to be irradiated with the beam twice at the minimum multiplicity. For example, as illustrated in FIG. 11, the required irradiation amount for the divided region DR3 which has the lowest required irradiation amount among the divided regions DR1 to DR3 is 58 μC. Therefore, as illustrated in FIG. 10, the beam irradiation amount setting unit 116 sets the beam irradiation amounts in the first and second irradiations S1 and S2 so that the irradiation amount of 58 μC is achieved by irradiating two times, which is the minimum multiplicity. Further, the scan setting unit 114 sets the irradiation regions of the first and second irradiations S1 and S2 for the divided regions DR1 to DR3 (the entire drawing region). Accordingly, the total irradiation amount for the divided regions DR1 to DR3 becomes 58 μC. At this time, the total irradiation amount for the divided region DR3 becomes the required irradiation amount or more. Therefore, the beam irradiation for the divided region DR3 is no longer necessary.

Next, the drawing device 100 is set so that the third and fourth irradiations at the maximum multiplicity (third and fourth irradiations S3 and S4) satisfy the required irradiation amount for the entire drawing region. For example, the required irradiation amount for the divided region DR2 is 72 μC, and the total irradiation amount already applied in the first and second irradiations S1 and S2 is 58 μC. Therefore, as illustrated in FIG. 10, the beam irradiation amount setting unit 116 sets the beam irradiation amount in the third irradiation S3 so that the irradiation amount in the third irradiation S3 is 14 μC. Further, the scan setting unit 114 sets the irradiation region in the third irradiation S3 for the divided regions DR1 and DR2. Accordingly, the total irradiation amount for the divided regions DR1 and DR2 becomes 72 μC. At this time, the total irradiation amount for the divided region DR2 becomes the required irradiation amount or more. Therefore, the beam irradiation for the divided region DR2 is no longer necessary.

Further, for example, the required irradiation amount for the divided region DR1 is 93 μC, and the total irradiation amount already applied in the first to third irradiations S1 to S3 is 72 μC. Therefore, as illustrated in FIG. 10, the beam irradiation amount setting unit 116 sets the beam irradiation amount in the fourth irradiation S4 so that the irradiation amount in the fourth irradiation S4 is 21 μC. Further, the scan setting unit 114 sets the irradiation region in the fourth irradiation S4 for the divided region DR1. Accordingly, the total irradiation amount for the divided region DR1 becomes 93 μC. At this time, the total irradiation amount for the divided region DR1 becomes the required irradiation amount or more. Therefore, by the first to fourth irradiations S1 to S4, corresponding to four times of irradiation, which is the maximum multiplicity, the total irradiation amount for the divided regions DR1 to DR3 (the entire drawing region) becomes the respective required irradiation amount or more.

Next, the drawing device 100 irradiates the substrate 101 with the beam according to the settings of the first to fourth irradiations S1 to S4 illustrated in FIG. 10.

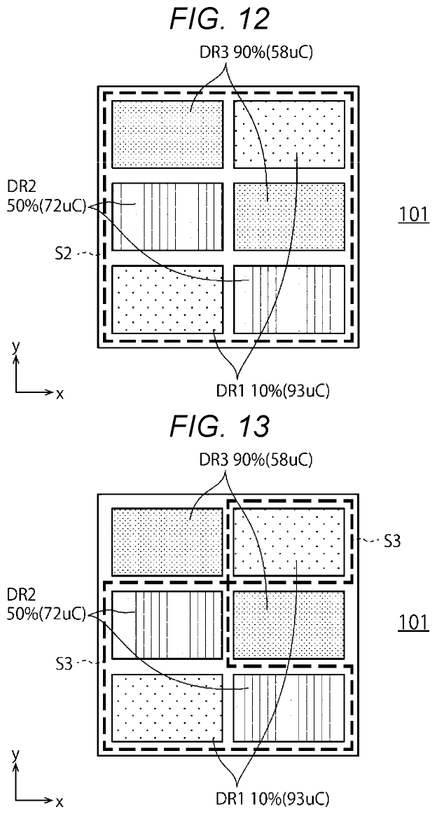

For example, FIGS. 11 to 14 are conceptual diagrams illustrating the drawing operation on the substrate by the drawing device according to the second embodiment. As illustrated in FIGS. 11 and 12, in the first and second irradiations S1 and S2, all of the divided regions DR1 to DR3 (the entire drawing region) are irradiated with the beam. At this time, the irradiation amount for the divided regions DR1 to DR3 is 29 μC. Therefore, the first and second irradiations S1 and S2 is performed with the beam up to the total irradiation amount of 58 μC. In this case, the total irradiation amount (58 μC) reaches the required irradiation amount (58 μC) for the divided region DR3. Therefore, no more beam irradiation is required for the divided region DR3.

Next, as illustrated in FIG. 13, in the third irradiation S3, the divided regions DR1 and DR2 are irradiated with the beam. At this time, the irradiation amount for the divided regions DR1 and DR2 is 14 μC. Therefore, in the third irradiation S3, the beam with the total irradiation amount of up to 72 μC is irradiated. In this case, the total irradiation amount (72 μC) reached the required irradiation amount (72 μC) for the divided region DR2. Therefore, no further beam irradiation is required for the divided region DR2.

Next, as illustrated in FIG. 14, in the fourth irradiation S4, the divided region DR1 is irradiated with the beam. At this time, the irradiation amount for the divided region DR1 is 21 μC. Therefore, in the fourth irradiation S4, the beam with the irradiation amount of 93 μC is irradiated. In this case, the total irradiation amount (93 μC) reached the required irradiation amount (93 μC) for the divided region DR1. Accordingly, the total irradiation amount for the divided regions DR1 to DR3 (the entire drawing region) becomes the respective required irradiation amount or more.

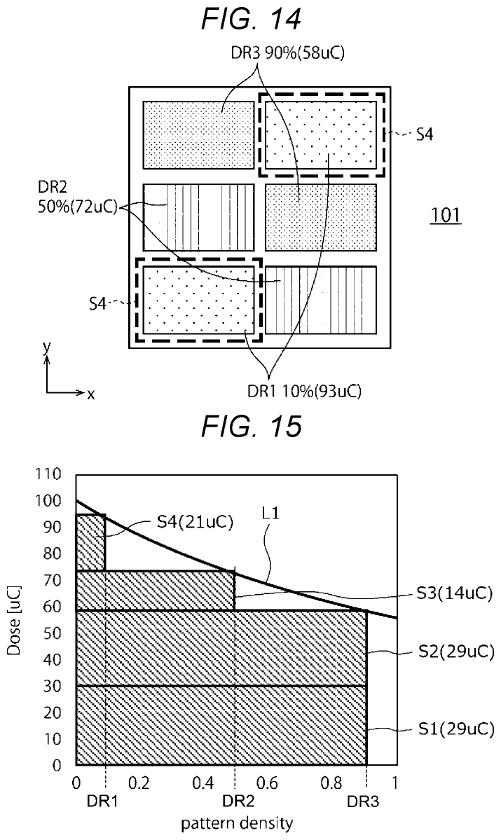

FIG. 15 is a graph illustrating a relationship between the pattern density and the irradiation amount. The vertical axis, the horizontal axis, L1, and the required irradiation amount for the divided regions DR1 to DR3 are the same as those in FIG. 9. On the other hand, it can be understood that in the second embodiment, the total irradiation amount for each of the divided regions DR1 to DR3 is approximately equal to their required irradiation amount.

In this manner, according to the second embodiment, the beam irradiation amount in the first to fourth irradiations can be varied based on the drawing conditions and the pattern density. Therefore, the control computer 110 can allow the respective total irradiation amounts for the divided regions DR1 to DR3 to be closer to or approximately equal to the required irradiation amount in the first to fourth irradiations. Accordingly, wasteful stage movement can be reduced.

The other configurations and operations of the second embodiment may be the same as the corresponding configurations and operations of the first embodiment. Therefore, the second embodiment can also obtain the same effects as the first embodiment.

### Modified Example

The irradiation amount may be changed by adjusting the beam irradiation time. For the divided regions where the pattern density is high and close to 1, the beam irradiation amount may be small. In this case, the drawing control unit 118 may increase the moving speed of the XY stage 105. For the divided regions where the pattern density is low and the required irradiation amount is high, the drawing control unit 118 allows the stage speed to be slow, and for the divided regions where the pattern density is high and the required irradiation amount is low, the drawing control unit 118 allows the speed of the XY stage 105 to be high. Accordingly, since the beam irradiation is performed while changing the speed of the XY stage 105, the drawing time can be shortened.

Even within the same divided region, when the beam irradiation shifts from the region with the high pattern density to the region with the low pattern density, the drawing control unit 118 may allow the speed of the XY stage 105 to be low. By controlling the speed of the XY stage 105 in this manner, the drawing time can be shortened even if sparse patterns are mixed in the same divided region.

### Third Embodiment

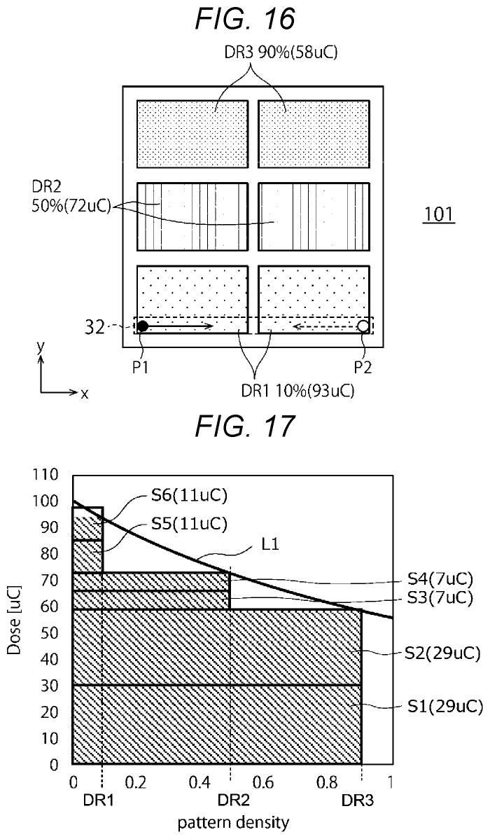

FIG. 16 is a conceptual diagram illustrating a drawing operation on a substrate by a drawing device according to a third embodiment. FIG. 17 is a graph illustrating a relationship between a pattern density and an irradiation amount according to the third embodiment. The vertical axis, horizontal axis, L1, and required irradiation amount for the divided regions DR1 to DR3 in FIG. 17 are the same as those in FIG. 9 or FIG. 15.

In the third embodiment, the number of times (multiplicity) with which the beam is irradiated repeatedly for each of the divided regions DR1 to DR3 is an even number. For example, as illustrated in FIG. 17, the drawing device 100 irradiates the divided regions DR1 to DR3 with the beam twice of first and second irradiations S1 and S2. At this time, as illustrated in FIG. 16, the drawing device 100 starts the first irradiation S1 from an irradiation start position P1 and irradiates the first stripe region 32 with the beam in the +x direction. At this time, the drawing device 100 irradiates the drawing region with the beam by using the raster scan method. That is, the drawing device 100 draws the stripe region 32 by reciprocating the beam.

Next, the drawing device 100 starts the second irradiation S2 from an irradiation start position P2 and irradiates the first stripe region 32 with the beam in the −x direction. At this time, the drawing device 100 irradiates the drawing region with the beam by using the raster scan method. If the irradiation amount in the first and second irradiations S1 and S2 is 29 μC, the total irradiation amount for the divided regions DR1 to DR3 is 58 μC due to the first and second irradiations S1 and S2. Accordingly, the total irradiation amount for the divided region DR3 becomes the required irradiation amount or more.

The irradiation start position P2 is located on the opposite side of the drawing region (opposite side of the stripe region 32 in the x direction) with respect to the irradiation start position P1. Furthermore, in each of the stripe regions 32, the moving directions of the stage are opposite to each other in the first irradiation S1 and the second irradiation S2. Therefore, in the first and second irradiations S1 and S2, the drawing device 100 moves the stage in directions opposite to each other to perform the beam irradiation.

Next, as illustrated in FIG. 17, the drawing device 100 additionally irradiates the divided regions DR1 and DR2 with the beam twice, that is, the third and fourth irradiations S3 and S4. That is, the divided regions DR1 and DR2 are irradiated with the beam four times, that is, the first to fourth irradiations S1 to S4. At this time, similarly to the above, the drawing device 100 starts the third irradiation S3 from the irradiation start position P1, moves the stage in the +x direction, and irradiates the first stripe region 32 with the beam. At this time, the drawing device 100 irradiates the divided regions DR1 and DR2 with the beam by using the raster scan method.

Next, the drawing device 100 starts the fourth irradiation S4 from the irradiation start position P2, moves the stage in the −x direction, and irradiates the first stripe region 32 with the beam. At this time, the drawing device 100 irradiates the divided regions DR1 and DR2 with the beam by using the raster scan method. If it is assumed that the irradiation amount in the third and fourth irradiations S3 and S4 is 7 μC, the irradiation amount for the divided regions DR1 and DR2 is added by 14 μC by the third and fourth irradiation S3 and S4, and their total irradiation amount is 72 μC. Accordingly, the total irradiation amount for the divided region DR2 becomes the required irradiation amount or more.

The irradiation start position P2 is located on the opposite side of the drawing region (opposite side of the stripe region 32 in the x direction) with respect to the irradiation start position P1. Further, in each of the stripe regions 32, the stage movement directions are opposite to each other in the third irradiation S3 and the fourth irradiation S4. Therefore, in the third and fourth irradiations S3 and S4, the drawing device 100 moves the stage in directions opposite to each other and performs the beam irradiation.

Next, as illustrated in FIG. 17, the drawing device 100 additionally irradiates the divided region DR1 with the beam twice, that is, fifth and sixth irradiations S5 and S6. That is, the divided region DR1 is irradiated with the beam six times, that is, the first to sixth irradiations S1 to S6. At this time, similarly to the above, the drawing device 100 starts the fifth irradiation S5 from the irradiation start position P1, moves the stage in the +x direction, and irradiates the first stripe region 32 with the beam. At this time, the drawing device 100 irradiates the divided region DR1 with the beam by using the raster scan method.

Next, the drawing device 100 starts the sixth irradiation S6 from the irradiation start position P2, moves the stage in the −x direction, and irradiates the first stripe region 32 with the beam. At this time, the drawing device 100 irradiates the divided region DR1 with the beam by using the raster scan method. If it is assumed that the irradiation amount in the fifth and sixth irradiations S5 and S6 is 11 μC, the irradiation amount for the divided region DR1 is added by 22 μC by the fifth and sixth irradiations S5 and S6, and their total irradiation amount is 94 μC. Accordingly, the total irradiation amount for the divided region DR1 becomes the required irradiation amount or more.

The irradiation start position P2 is located on the opposite side (opposite side of the stripe region 32 in the x direction) of the drawing region with respect to the irradiation start position P1. Further, in each of the stripe regions 32, the directions in which the stage is moved and the beam irradiation is performed are opposite to each other in the fifth irradiation S5 and the sixth irradiation S6. Therefore, in the fifth and sixth irradiations S5 and S6, the drawing device 100 moves the stage in directions opposite to each other and performs the beam irradiation.

In this manner, the number of irradiations of the beam is an even number in all of the divided regions DR1 to DR3. Furthermore, in each of the stripe regions 32, the scan direction of the beam is such that one half of the first to sixth irradiations S1 to S6 of the beam (for example, S1, S3, S5) and the other half of the irradiations (S2, S4), S6) are in directions opposite to each other.

If the number of irradiations of the beam is an odd number, or if the scan direction of the beam is biased in one direction, the position deviation amount for the pattern formed on the resist may become large.

Meanwhile, according to the third embodiment, the number of irradiations of the beam is an even number in any of the divided regions DR1 to DR3, and the beam scan direction is set so that a half of the irradiations (for example, S1, S3, S5) among the first to sixth beam irradiations S1 to S6, and the other half of the irradiations (S2, S4, S6) are in directions opposite to each other. Therefore, a position deviation amount for the pattern formed on the resist can be canceled and reduced.

### Fourth Embodiment

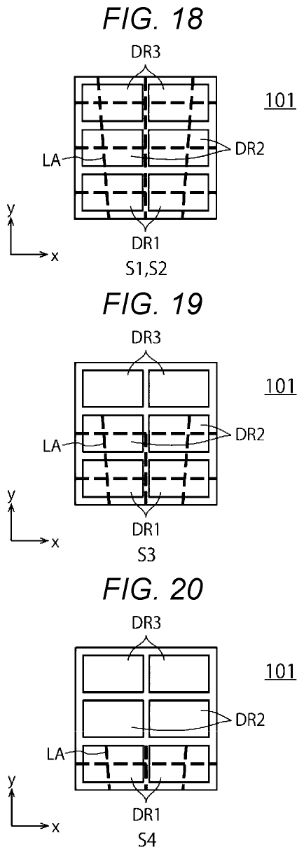

FIGS. 18 to 20 are conceptual plan views of a substrate illustrating an irradiation position correction process according to a fourth embodiment. In the fourth embodiment, the control computer 110 corrects the beam irradiation position in consideration of thermal expansion of the substrate 101 due to the beam irradiation. For example, as illustrated by an auxiliary line LA in FIG. 18, in the first irradiation S1 and the second irradiation S2, when the beam irradiation progresses from the bottom to the top of the substrate 101, the substrate 101 is heated by the beam to be thermally expanded. Therefore, the control computer 110 corrects the beam irradiation position by the amount of the thermal expansion of the substrate 101 based on the total beam irradiation amount. Due to the beam irradiation, the temperature of the substrate 101 at the end of the beam scan is higher than that at the start of the beam scan. Therefore, a correction amount of the beam at the end of the beam scan is larger than that at the start of the beam scan.

For example, the storage unit 140 stores in advance information (a relational expression) on a temperature change of the substrate 101 with respect to the beam irradiation amount and a thermal expansion coefficient of the substrate 101. The control computer 110 calculates the temperature of the substrate 101 from the total irradiation amount of the beam based on the relational expression of the temperature change with respect to the beam irradiation amount and calculates the thermal expansion of the substrate 101 from the temperature of the substrate 101 and the thermal expansion coefficient of the substrate 101. Then, the control computer 110 calculates the correction amount of the beam irradiation position according to the thermal expansion of the substrate 101. The control computer 110 calculates the correction amount of the beam irradiation position in each of the first to fourth irradiations S1 to S4. When performing the first and second irradiations S1 and S2, the drawing device 100 irradiates the drawing region with the beam in consideration of this correction amount. It is noted that the temperature of the substrate 101 approaches the substrate temperature before drawing over time. Therefore, the relational expression of the temperature change of the substrate 101 with respect to the beam irradiation amount is also the function of time.

As illustrated by the auxiliary line LA in FIG. 19, in the third irradiation S3 as well, when the beam irradiation progresses from the bottom to the top of the divided regions DR1 and DR2 of the substrate 101, the substrate 101 is heated by the beam to be thermally expanded. Therefore, the control computer 110 corrects the beam irradiation position by the amount of thermal expansion of the substrate 101 based on the total beam irradiation amount. In the third irradiation S3 as well, the correction amount of the beam is larger at the end of the beam scan than at the start of the beam scan.

As illustrated by the auxiliary line LA in FIG. 20, similarly in the fourth irradiation S4, when the beam irradiation progresses from the bottom to the top of the divided region DR1 of the substrate 101, the substrate 101 is heated by the beam to be thermally expanded. Therefore, the control computer 110 corrects the beam irradiation position by the amount of thermal expansion of the substrate 101 based on the total beam irradiation amount. In the fourth irradiation S4 as well, the correction amount of the beam is larger at the end of the beam scan than at the start of the beam scan.

In this manner, according to the fourth embodiment, the beam irradiation position is corrected in consideration of the thermal expansion of the substrate 101 due to the beam irradiation. Accordingly, when the temperature of the substrate 101 returns to the substrate temperature before the drawing after the beam irradiation, the accurate pattern is drawn in the drawing region of the substrate 101. As a result, the drawing device 100 can draw the highly accurate pattern on the drawing region of the substrate 101. Other configurations and operations of the fourth embodiment may be the same as any of the first to third embodiments. Accordingly, the fourth embodiment can also obtain the effects of any of the first to third embodiments.

### Fifth Embodiment

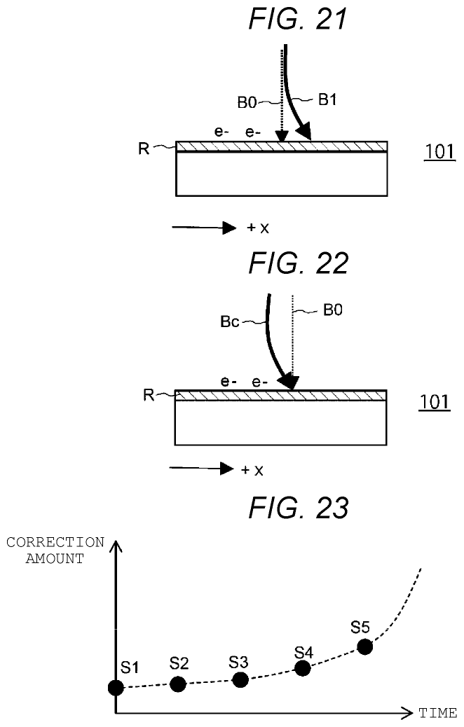

FIGS. 21 and 22 are conceptual cross-sectional views of the substrate illustrating an irradiation position correction process according to a fifth embodiment. In the fifth embodiment, the control computer 110 corrects the beam irradiation position in consideration of the charge-up of the charges of the substrate 101 due to the beam irradiation. For example, if the beam irradiation is performed based on the drawing pattern and the beam is the charged particles having the negative charges, the resist material R irradiated with the beam is charged up with charges (electrons) as illustrated in FIG. 21. Therefore, as illustrated in FIG. 21, when the beam irradiation with a beam B1 is performed near the previously drawn pattern portion, the beam irradiation position deviates from the irradiation position of a beam B0 that should originally be irradiated.

Meanwhile, as illustrated in FIG. 22, the control computer 110 according to the fifth embodiment corrects the irradiation position of a beam Bc in order to correct the beam position deviation due to the charge-up of the charges of the previously drawn pattern portion with respect to the beam irradiation position. Accordingly, the irradiation position of the after-correction beam Bc can approach the irradiation position of the beam B0 that should originally be irradiated.

For example, the storage unit 140 stores in advance the relational expression between the beam irradiation amount and the charge amount remaining in the resist material and the relational expression of the beam deviation amount due to the charge amount remaining in the resist material. The control computer 110 calculates the charge amount remaining in the resist material from the beam irradiation amount, and calculates the correction amount of the beam from the charge amount remaining in the resist material. The control computer 110 calculates the correction amount of the beam irradiation position for each of the first to fourth irradiations S1 to S4. When performing the beam irradiation, the drawing device 100 irradiates the drawing region with the beam in consideration of this correction amount. Accordingly, the beam irradiation position can be corrected by the charge amount that is charged up in the resist material of the substrate 101. As a result, the drawing device 100 can draw the highly accurate pattern on the drawing region of the substrate 101.

FIG. 23 is a graph illustrating a relationship between the correction amount of the beam irradiation position and the beam irradiation time. The charge amount that is charged up to the resist material increases as the number of irradiations (multiplicity) increases, but the charge amount disappears with the passage of time. Therefore, the correction amount of the beam irradiation position is expressed as illustrated in the graph of FIG. 23 based on the relationship between the number of irradiations (multiplicity) and time. The storage unit 140 may store in advance the relational expression between the correction amount of the beam irradiation position, the number of irradiations (multiplicity), and time. Accordingly, the control computer 110 can calculate the correction amount in consideration of the passage of time.

As described above, according to the fifth embodiment, the beam irradiation position is corrected in consideration of the charges on the substrate 101 due to the beam irradiation. Accordingly, the accurate pattern is drawn in the drawing region of the substrate 101. Other configurations and operations of the fifth embodiment may be the same as any of the first to third embodiments. Accordingly, the fifth embodiment can also obtain the effects of any of the first to third embodiments. Further, the fifth embodiment may be combined with the fourth embodiment. Accordingly, the drawing device 100 can correct the beam irradiation position in consideration of the thermal expansion of the substrate 101 and the charges of the resist material.

As described above, by processing the resist formed on the substrate (mask blank, template blank, semiconductor substrate) by using the drawing device and the correction process of the first to fifth embodiments, the desired photomask, template, and the like can be manufactured.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A drawing device comprising:
a device configured to generate a beam of charged particles;
a group of optical elements disposed in a path of the beam, the group of optical elements being controlled so that the beam irradiates each of a plurality of divided regions of a target drawing region on which a pattern is to be drawn with the beam; and
a control computer configured to divide the target drawing region into the divided regions based on a density of the pattern, and to execute first to n-th irradiations (n is an integer of 2 or more) selectively on the divided regions so that a total irradiation amount of the beam on each of the divided regions reaches a required irradiation amount therefor.

2. The drawing device according to claim 1, wherein
the irradiation amounts of the beam in the first to n-th irradiations are equal, and
the control computer selects which of the divided regions is to be irradiated with the beam in each of the first to n-th irradiations and determines the total irradiation amount in each of the divided regions according to whether or not the divided region was selected to be irradiated with the beam in the first to n-th irradiations.

3. The drawing device according to claim 1, wherein the total irradiation amount of the beam in each of the divided regions is a sum of the irradiation amounts of the beam irradiated thereon in the first to n-th irradiations.

4. The drawing device according to claim 1, wherein the control computer determines the total irradiation amount of the beam on each of the divided regions after each of the first to n-th irradiations, and does not execute a next irradiation in the first to n-th irradiations on a divided region if the total irradiation amount of the beam determined for the divided region has reached the required irradiation amount for the divided region.

5. The drawing device according to claim 1, wherein the control computer calculates the density of the pattern in different regions of the target drawing region based on input drawing data, and divides the target drawing region into the plurality of divided regions based on the density of the pattern in the different regions.

6. The drawing device according to claim 1, wherein the control computer changes the irradiation amount of the beam in the first to n-th irradiations, and determines whether to perform the first to n-th irradiations on each of the divided regions based on a comparison of the total irradiation amount of the beam on the divided region and the required irradiation amount for the divided region.

7. The drawing device according to claim 6, wherein the control computer determines the irradiation amount of the beam in each of the first to n-th irradiations based on a multiplicity requirement, which relates to the number of times the target drawing region is irradiated repeatedly with the beam.

8. The drawing device according to claim 7, wherein the multiplicity requirement includes a minimum multiplicity indicating the minimum number of times that the divided regions should be irradiated repeatedly with the beam, and a maximum multiplicity indicating the maximum number of times that the divided regions are allowed to be irradiated repeatedly with the beam.

9. The drawing device according to claim 8, wherein the control computer determines the irradiation amount of the beam in each of the first to n-th irradiations so that all of the divided regions are repeatedly irradiated with the beam at least a number of times equal to the minimum multiplicity and at least one of the divided regions is repeatedly irradiated with the beam a number of times equal to the maximum multiplicity.

10. The drawing device according to claim 1, wherein n of the first to n-th irradiations is an even number.

11. The drawing device according to claim 1, further comprising:
a stage on which a substrate with the target drawing region is to be placed, wherein the control computer controls the stage to move so that the beam that is incident on the target drawing region scans stripe regions of the target drawing region in opposite directions.

12. The drawing device according to claim 11, wherein a width of the stripe regions is about equal to a width of the beam.

13. The drawing device according to claim 12, wherein the control computer controls the stage to move in a first direction during half of the first to n-th irradiations and to move in a second direction that is opposite to the first direction during the other half of the first to n-th irradiations.

14. A method of drawing a pattern on a target drawing region that is divided into a plurality of divided regions based on a density of the pattern, said method comprising:
generating a beam of charged particles;
controlling a group of optical elements disposed in a path of the beam, so that the beam irradiates each of the divided regions; and
executing first to n-th irradiations (n is an integer of 2 or more) selectively on the divided regions so that a total irradiation amount of the beam on each of the divided regions reaches a required irradiation amount therefor.

15. The method according to claim 14, further comprising:
determining the total irradiation amount of the beam on each of the divided regions after each of the first to n-th irradiations, wherein
a next irradiation in the first to n-th irradiations is not executed on a divided region if the total irradiation amount of the beam determined for the divided region has reached the required irradiation amount for the divided region.

16. The method according to claim 15, wherein the irradiation amounts of the beam in the first to n-th irradiations are equal.

17. The method according to claim 14, further comprising:
calculating the density of the pattern in different regions of the target drawing region based on input drawing data, and dividing the target drawing region into the plurality of divided regions based on the density of the pattern in the different regions.

18. The method according to claim 14, wherein
during the first to n-th irradiations, moving a stage on which a substrate with the target drawing region is placed.

19. The method according to claim 18, wherein the stage is moved so that the beam that is incident on the target drawing region scans stripe regions of the target drawing region in opposite directions.

20. The method according to claim 19, wherein a width of the stripe regions is about equal to a width of the beam.
